(19) United States
(12) Patent Application Publication
(10) Pub. No.: US 2013/0181278 A1
(43) Pub. Date: Jul. 18, 2013

(54) NON-VOLATILE MEMORY DEVICE AND METHOD FOR FABRICATING THE DEVICE

(71) Applicants: Sung-Hun LEE, Yongin-si (KR); Sung-Hoi Hur, Seoul (KR); Jong-Ho Park, Seoul (KR)

(72) Inventors: Sung-Hun LEE, Yongin-si (KR); Sung-Hoi Hur, Seoul (KR); Jong-Ho Park, Seoul (KR)

(21) Appl. No.: 13/608,796

(22) Filed: Sep. 10, 2012

(30) Foreign Application Priority Data
Jan. 12, 2012 (KR) 10-2012-0003915

(51) Int. Cl. H01L 29/792

(52) U.S. Cl. 257/324; 257/E29.309

(57) ABSTRACT

Provided is a non-volatile memory device that includes a substrate including a plurality of active regions extending in a first direction and a plurality of element isolation trenches disposed between the active regions, a plurality of tunnel insulating layer patterns and a plurality of storage layer patterns sequentially disposed on the substrate, a plurality of blocking insulating layers and a plurality of gate electrodes disposed on the storage layer patterns and extending in a second direction perpendicular to the first direction, and first insulating layers including air gaps disposed between the active regions on the element isolation trenches and extending in the first direction, wherein the active regions include first active regions and second active regions adjacent to the first active regions, wherein a width of first air gaps is different from a width of second air gaps.

### CROSS-REFERENCE TO RELATED APPLICATION

This application claims priority to Korean Patent Application No. 10-2012-0003915 filed on Jan. 12, 2012 in the Korean Intellectual Property Office under 35 U.S.C. 119, the contents of which are herein incorporated by reference in its entirety.

### TECHNICAL FIELD

Embodiments of the present inventive concept relate to a non-volatile memory device and a method for fabricating the device.

### DISCUSSION OF THE RELATED ART

Non-volatile memory devices do not lose stored data even when power supply is turned off. Examples of the non-volatile memory devices include programmable read-only memories (PROMs), erasable PROMs (EPROMs), electrically EPROMs (EEPROMs), flash memory devices and the like. Flash memory devices electrically program and erase data by using Fowler-Nordheim (FN) tunneling or channel hot electron injection.

As memory devices have higher capacity and integration, the size of memory cells in the memory device reduces, thus resulting in an increase in a coupling of signal lines, which may cause erroneous memory cell operations.

### SUMMARY

Embodiments of the present invention provide a non-volatile memory device with increased reliability and a method for fabricating the non-volatile memory device.

According to an embodiment of the present invention, there is provided a non-volatile memory device including a substrate including a plurality of active regions sequentially disposed and extending in a first direction and a plurality of element isolation trenches disposed between the active regions, a plurality of tunnel insulating layer patterns and a plurality of storage layer patterns sequentially disposed on the substrate, a plurality of blocking insulating layers and a plurality of gate electrodes sequentially disposed on the storage layer patterns and extending in a second direction perpendicular to the first direction, and first insulating layers including air gaps disposed between the active regions in the element isolation trenches, wherein the first insulating layers extend in the first direction, wherein the active regions include first active regions and second active regions adjacent to the first active regions, wherein the air gaps include first air gaps disposed between the first active regions and second air gaps disposed between the second active regions, and wherein a width of the first air gaps is different from a width of the second air gaps.

According to an embodiment of the present invention, there is provided a non-volatile memory device including a substrate including a plurality of active regions sequentially disposed and extending in a first direction and a plurality of element isolation trenches disposed between the active regions, a plurality of tunnel insulating layer patterns and a plurality of storage layer patterns sequentially disposed on the substrate, a plurality of blocking insulating layers and a plurality of gate electrodes sequentially disposed on the storage layer patterns and extending in a second direction perpendicular to the first direction, first air gaps disposed between the active regions and extending in the first direction, and second air gaps disposed between the gate electrodes and extending in the second direction, wherein a width of some of the first air gaps that intersect the second air gaps is different from a width of others of the first air gaps that do not intersect the second air gaps.

According to an embodiment of the present invention, there is provided a method of fabricating a memory device, the method including forming a plurality of trenches and a plurality of active regions on a substrate, wherein the active regions include first active regions and second active regions, and the trenches include first trenches between the first active regions and second trenches between the second active regions, sequentially forming a plurality of tunnel insulating layer patterns and a plurality of storage layer patterns on the active regions, sequentially forming a first material layer, a sacrifice layer, and a second material layer in the trenches, wherein the second material layer is formed to expose portions of the sacrifice layer, selectively removing the sacrifice layer, forming a third material layer on the second material layer to form first air gaps in the first trenches and second air gaps in the second trenches, sequentially forming a dielectric layer and a conductive layer on the substrate, removing portions of the dielectric layer, the conductive layer, the storage layer patterns, and the tunnel insulating layer patterns to expose the second active regions and the second trenches, wherein the second trenches are larger in width and depth than the first trenches.

### BRIEF DESCRIPTION OF THE DRAWINGS

The embodiments of the present invention will become more apparent by the detailed description with reference to the attached drawings, in which:

FIG. 1 is a block diagram illustrating a non-volatile memory device in accordance with an embodiment of the present invention;

FIG. 2 is a circuit diagram illustrating the cell array region of FIG. 1;

FIG. 3 is a layout diagram illustrating the cell array region of FIG. 1;

FIG. 4 is an enlarged layout diagram showing region C of FIG. 3;

FIG. 5 is a cross-sectional view taken along lines I-I′, II-II′ and

FIGS. 6 to 12 illustrate a method for fabricating a non-volatile memory device in accordance with an embodiment of the present invention;

FIG. 13 is a block diagram for describing a memory system in accordance with an embodiment of the present invention;

FIG. 14 is a block diagram showing an application example of the memory system of FIG. 13; and

FIG. 15 is a block diagram showing a computing system including the memory system described with reference to FIG. 14.

### DETAILED DESCRIPTION OF THE EMBODIMENTS

Embodiments of the present invention will be described with reference to the accompanying drawings. The present invention may, however, be embodied in many different forms and should not be construed as being limited to the embodiments set forth herein. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. Like numbers may refer to like or similar elements throughout the specification and the drawings.

The use of the terms “a” and “an” and “the” and similar referents in the context of describing the invention are to be construed to cover both the singular and the plural, unless otherwise indicated herein or clearly contradicted by context.

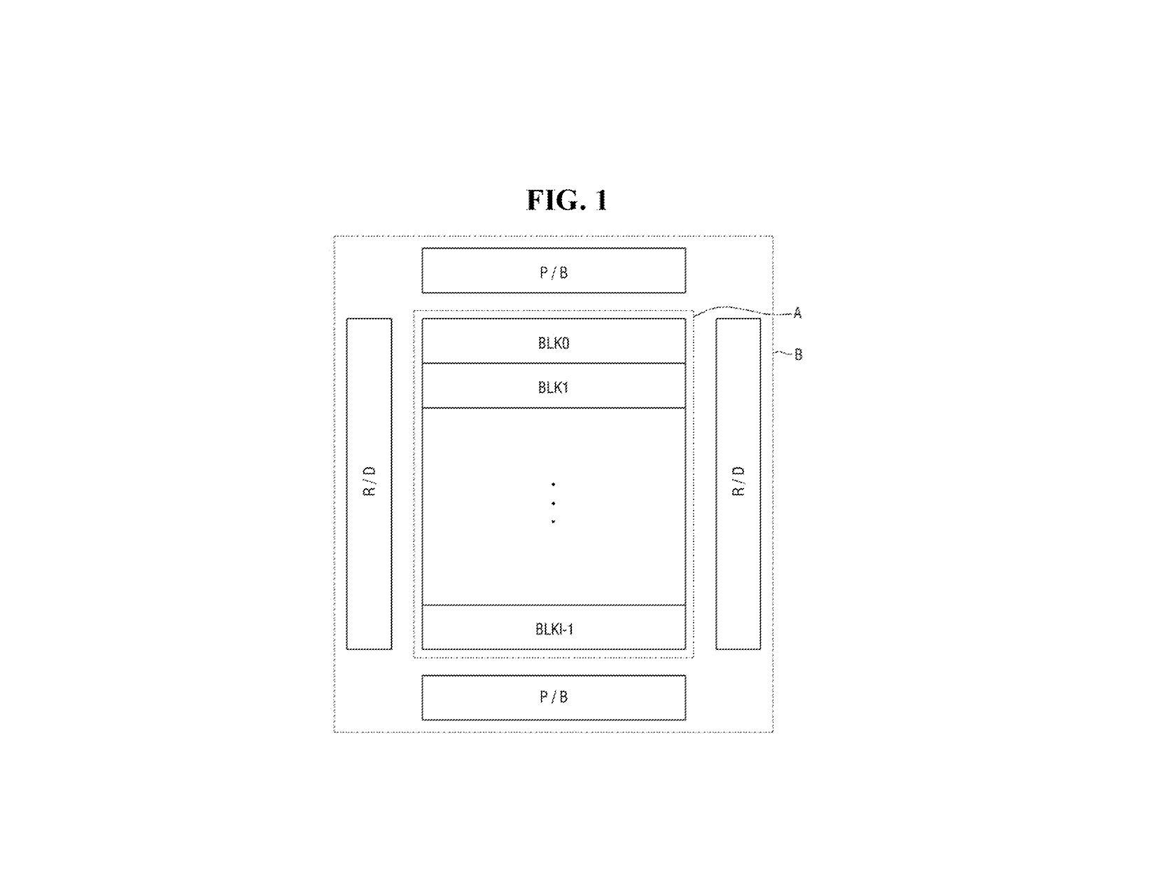

Hereinafter, embodiments of the present invention will be described with reference to FIGS. 1 to 5.

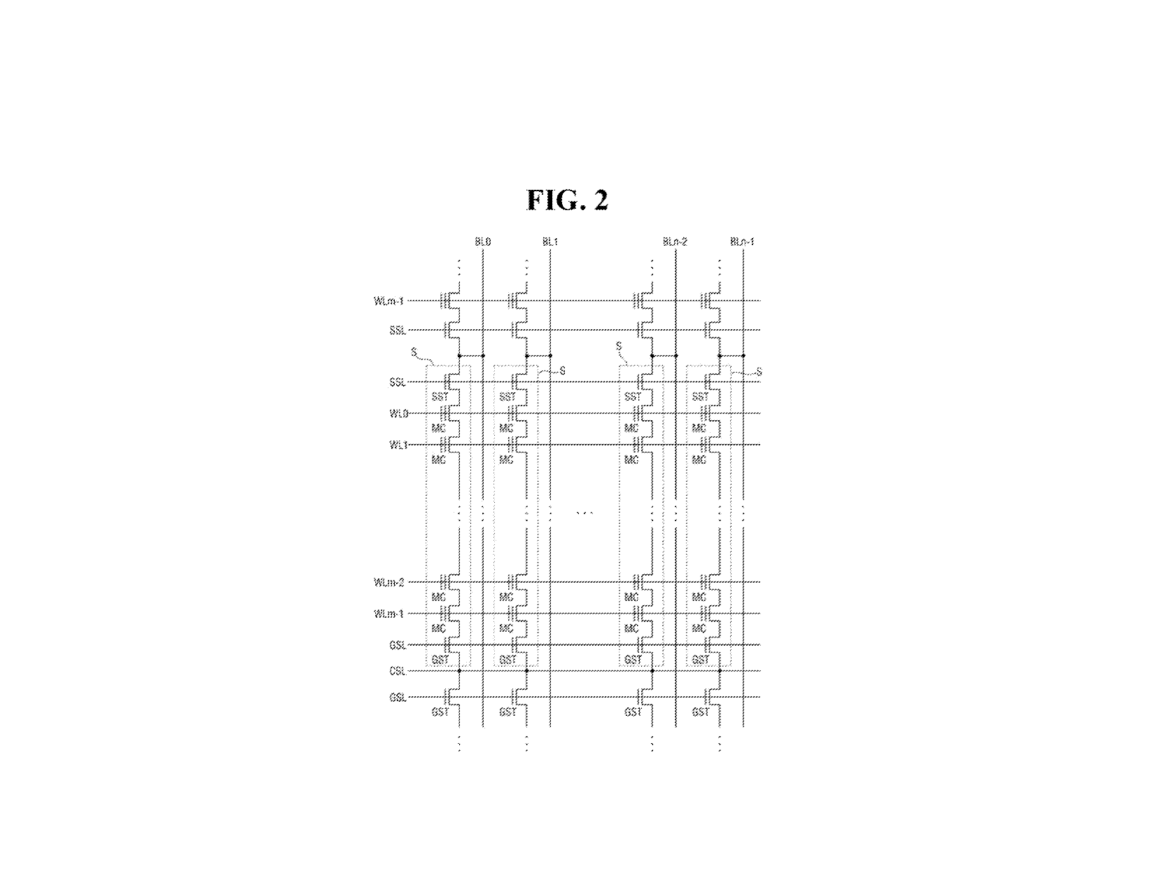

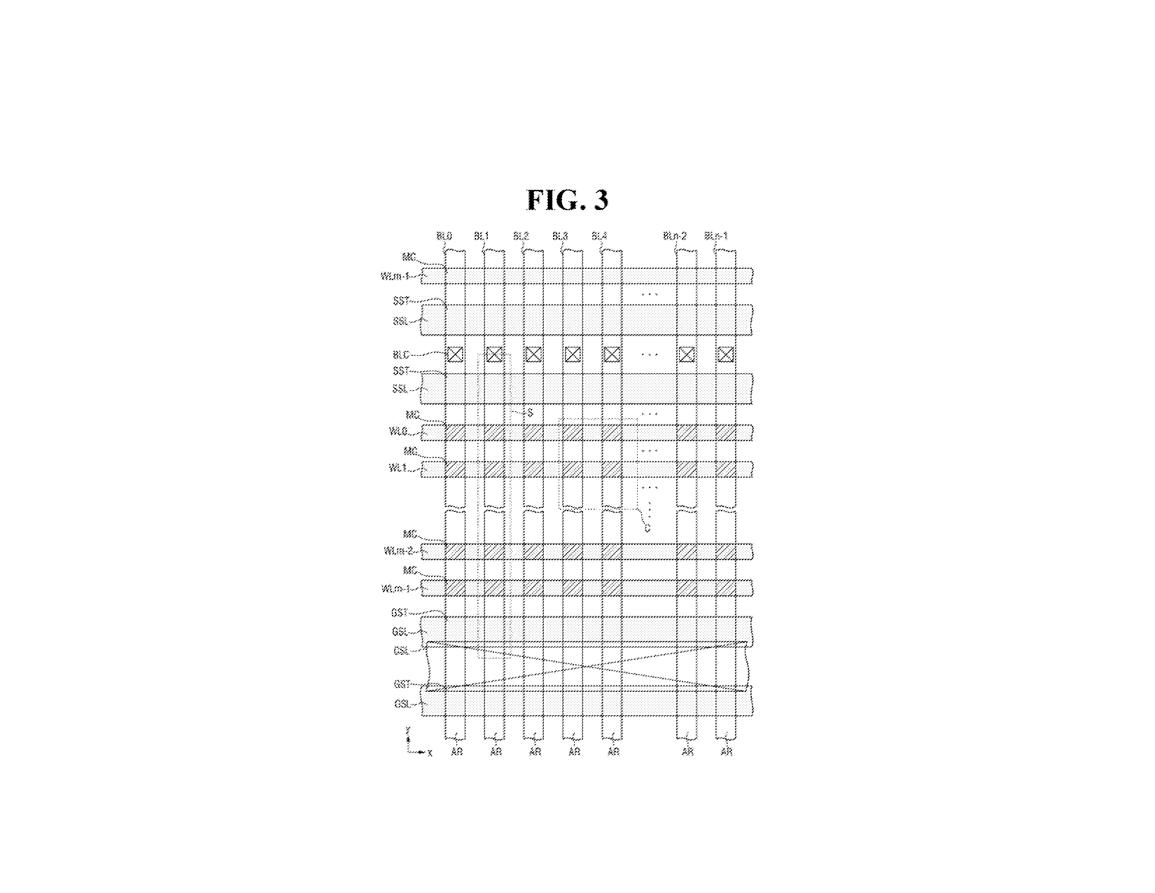

FIG. 1 is a block diagram illustrating a non-volatile memory device in accordance with an embodiment of the present invention. FIG. 2 is a circuit diagram illustrating the cell array region of FIG. 1, and FIG. 3 is a layout diagram illustrating the cell array region of FIG. 1.

Although a NAND-type flash memory device will be described as an example of the non-volatile memory device in accordance with embodiments of the present invention, the embodiments of the present invention are not limited thereto. The non-volatile memory device in accordance with the embodiments of the present invention may include a NOR-type flash memory device, a resistance change memory device, a phase change memory device, or a magnetic memory device.

Referring to FIGS. 1 to 3, a plurality of cell blocks BLK0 to BLK1-1 are sequentially arranged in a cell array region A of the non-volatile memory device (e.g.,

NAND type flash memory device). In each of the cell blocks BLK0 to BLK1-1, a plurality of active regions AR are arranged, and string selection lines SSL, ground selection lines GSL and a common source line CSL are arranged perpendicular to the active regions AR. A plurality of word lines WL0 to WLm-1 are arranged between the string selection lines SSL and the ground selection lines GSL. A plurality of bit lines BL0 to BLn-1 are arranged to intersect the word lines WL0 to WLm-1.

Memory cell transistors MC are respectively formed at areas where the bit lines BL0 to BLn-1 intersect the word lines WL0 to WLm-1. String selection transistors SST are respectively formed at areas where the bit lines BL0 to BLn-1 intersect the string selection lines SSL, and ground selection transistors GST are respectively formed at areas where the bit lines BL0 to BLn-1 intersect the ground selection lines GSL.

A string selection transistor SST, a plurality of the memory cell transistors MC, and a ground selection transistor GST are connected in series to thereby form one string S. Strings formed in each of the cell blocks BLK0 to BLK1-1 are connected substantially in parallel to the bit lines BL, respectively. A drain of the string selection transistor SST of each string S is connected to a corresponding one of the bit lines BL. A source of the ground selection transistor GST of each string S is connected to the common source line CSL.

Page buffers P/B are arranged at upper and lower sides of a peripheral circuit region B. Row decoders R/D are arranged at left and right sides of the peripheral circuit region B.

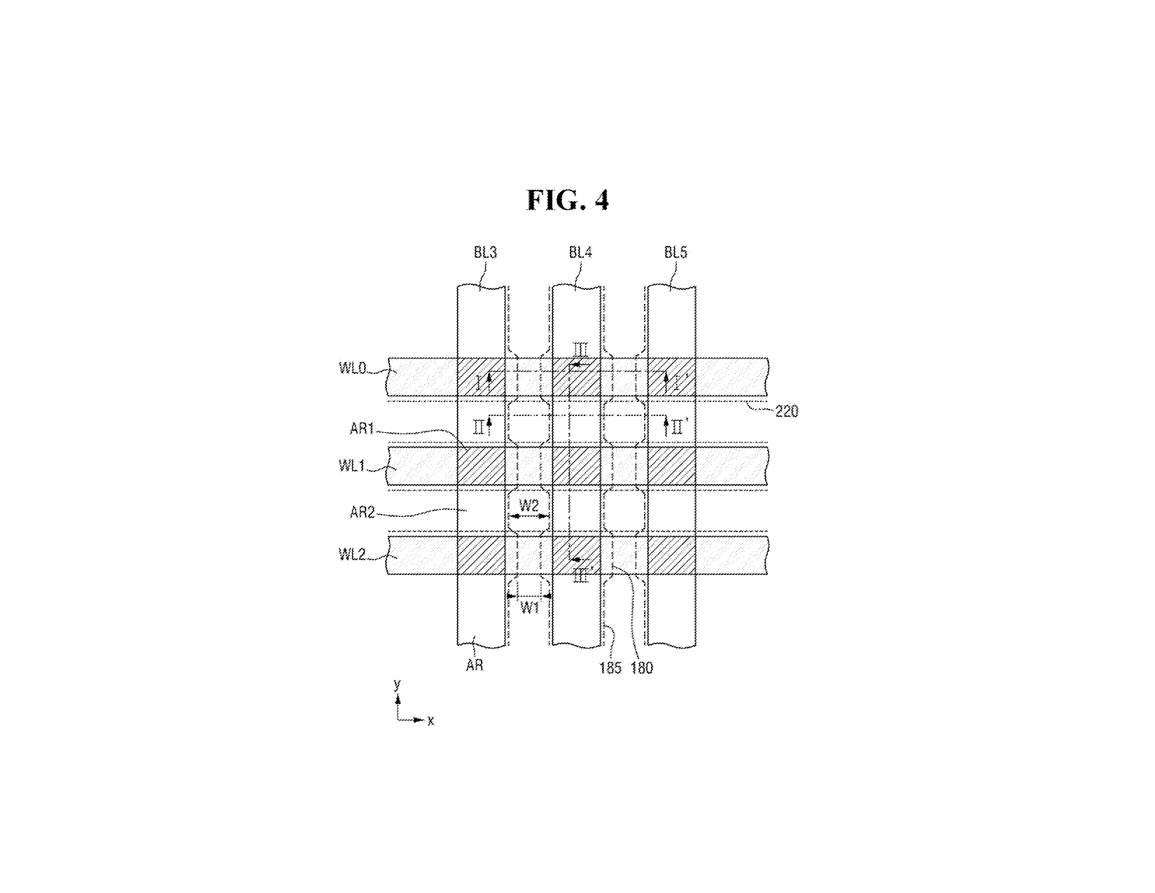

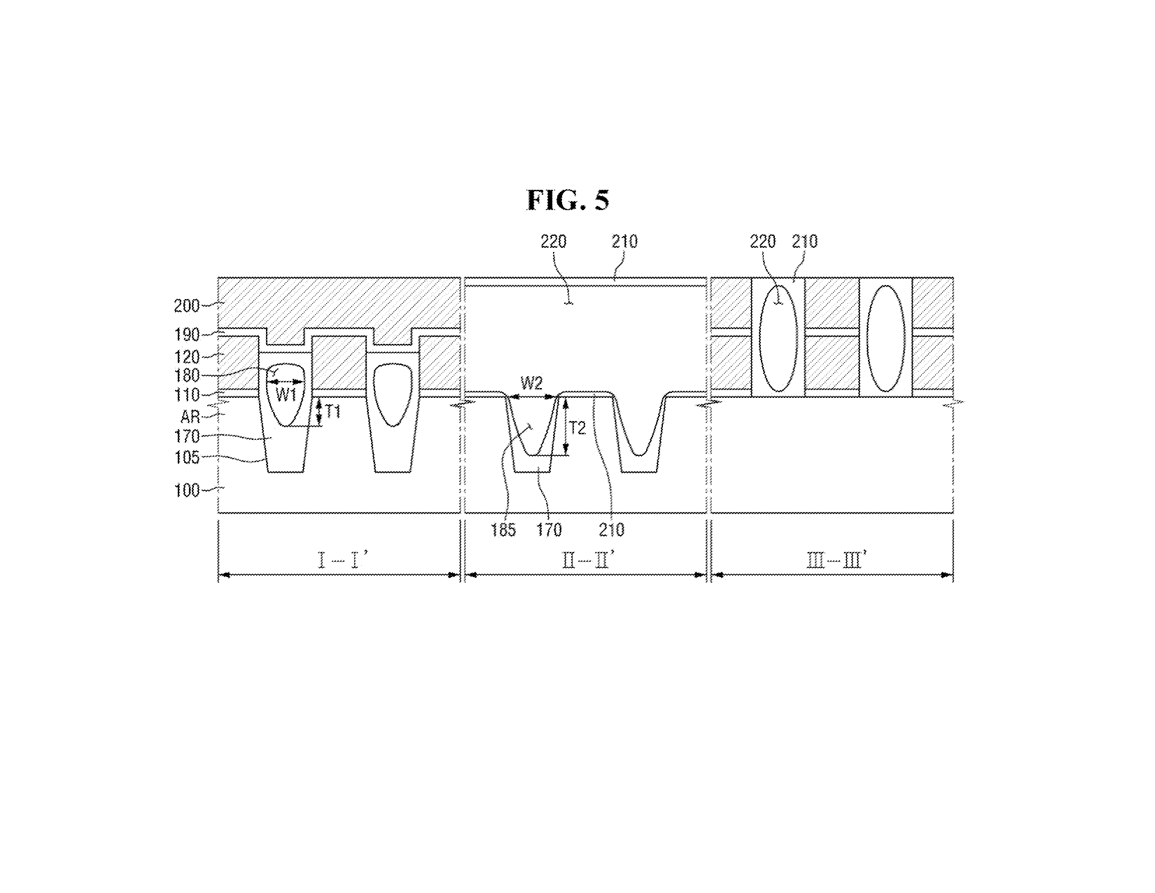

FIG. 4 is an enlarged layout diagram showing region C of FIG. 3. FIG. 5 is a cross-sectional view taken along lines I-I′, II-II′ and III-III′.

Referring to FIGS. 4 and 5, a substrate 100 includes a plurality of active regions AR sequentially arranged in an X direction and extending in a first direction (e.g., Y direction) and a plurality of element isolation trenches 105 disposed between the active regions AR. The cell array region A (see FIG. 1) and the peripheral circuit region B (see FIG. 1) are formed on the substrate 100, and a plurality of the active regions AR are sequentially arranged in the cell array region A (see FIG. 1).

According to an embodiment, the substrate 110 is formed of at least one semiconductor material selected from the group consisting of Si, Ge, SiGe, GaP, GaAs, SiC, SiGeC, InAs, or InP, but the embodiments of the present invention are not limited thereto. In an embodiment of the present invention, the substrate 100 includes a semiconductor-on-insulator (SOI) substrate.

According to an embodiment, a plurality of wells are formed in the substrate 110 and optimize characteristics of transistors formed in the cell array region A and the peripheral circuit region B. For example, according to an embodiment, pocket p-wells are formed in the cell array region A, and n-wells and p-wells are formed in the peripheral circuit region B. According to an embodiment, the wells formed in the cell array region A of the substrate 100 are formed in active regions AR2 exposed by gate electrodes 200 or the word lines WL0 to WLm-1.

A plurality of tunnel insulating layer patterns 110 and a plurality of storage layer patterns 120 are disposed on the substrate 100. Specifically, the tunnel insulating layer patterns 110 and the storage layer patterns 120 are disposed on the active regions AR of the substrate 100. The tunnel insulating layer patterns 110 and the storage layer patterns 120 are disposed in substantially the same pattern as the memory cell transistors MC formed in the cell array region A.

The tunnel insulating layer patterns 110 function as a tunneling layer. Accordingly, a material and thickness of the tunnel insulating layer patterns 110 are selected to be appropriate for tunneling of electrons. For example, the tunnel insulating layer patterns 110 are formed of a single layer or multiple layers that include at least one of SiO₂, HfₓO_{y}, AlₓO_{y}, ZrₓO_{y}, TaₓO_{y}, HfₓSi₁₋ₓO_{y}, or HfₓSi₁₋ₓO_{y}N_{z}, but the embodiments of the present invention are not limited thereto.

The storage layer patterns 120 store electrons tunneled through the tunnel insulating layer patterns 110. According to an embodiment, when the non-volatile memory device to be fabricated is a floating gatetype memory device, the storage layer patterns 120 are formed of polysilicon doped with impurities.

According to an embodiment, when the non-volatile memory device to be fabricated is a floating trap-type memory device, such as a metal oxide nitride oxide semiconductor (MONOS) memory device and a silicon oxide nitride oxide semiconductor (SONOS) memory device, the storage layer patterns 120 is formed of a material capable of trapping electrons, e.g., SiN, BN, or SiBN. According to an embodiment, when the non-volatile memory device to be fabricated is a floating trap-type memory device, the storage layer patterns 120 are non-conductive and are formed at a level lower than a level illustrated in FIG. 5.

A plurality of blocking insulating layers 190 and a plurality of gate electrodes 200 are sequentially disposed on the storage layer patterns 120 and extend in a second direction (e.g., X direction) perpendicular to the first direction (e.g., Y direction).

The blocking insulating layers 190 are inter-gate insulating layers and block charges stored in the storage layer patterns 120 from moving to the gate electrodes 200. According to an embodiment, the blocking insulating layers 190 is formed of a single layer or multiple layers using at least one of SiO₂, HfₓO_{y}, AlₓO_{y}, ZrₓO_{y}, TaₓO_{y}, HfₓSi₁₋ₓO_{y}, Or HfₓSi₁₋ₓO_{y}N_{z}, but the embodiments of the present invention are not limited thereto. The blocking insulating layers 190 are formed on first insulating layers 170 and the storage layer patterns 120. The gate electrodes 200 are formed on the blocking insulating layers 190.

In an embodiment, when the storage layer patterns 120 function as floating gates, the gate electrodes 200 function as control gates. The gate electrodes 200 form the word lines WL0 to WLm-1.

According to an embodiment, the gate electrodes 200 are formed of a single layer or multiple layers including two or more material layers. For example, according to an embodiment, the gate electrodes 200 are formed by sequentially stacking a lower conductive line and an upper conductive line, and the stack structure of the lower and upper conductive lines includes one of a stacked structure of metal and metal barrier layers, a stacked structure of metal and impurity-doped polycrystalline silicon layers, a stacked structure of two metal silicide layers, and a stacked structure of metal silicide and impurity-doped polycrystalline silicon layers.

According to an embodiment, Ni, Co, Ru-Ta, Ni-Ti, Ti-Al-N, Zr, Hf, Ti, Ta, Mo, Ta-Pt, Ta-Ti, or W-Ti is used as metal forming the gate electrodes 200, but the embodiments of the present invention are not limited thereto. According to an embodiment, WN, TiN, TaN, TaCN, or MoN is used as metal barrier forming the gate electrodes 200, and WSiₓ, CoSiₓ, or NiSiₓ is used as metal silicide forming the gate electrodes 200, but the embodiments of the present invention are not limited thereto.

The first insulating layers 170 are disposed on the element isolation trenches 105. The first insulating layers 170 and the element isolation trenches 105 extend in the first direction (e.g., Y direction). The first insulating layers 170 include air gaps 180 and 185 disposed between the active regions AR. The air gaps 180 and 185 included in the first insulating layers 170 extend in the first direction (e.g., Y direction).

The active regions AR include first active regions AR1 and second active regions AR2. First air gaps 180 are disposed between first active regions AR1 on which the tunnel insulating layer patterns 110, the storage layer patterns 120, the blocking insulating layers 190 and the gate electrodes 200 are disposed. Second air gaps 185 are disposed between second active regions AR2 on which second insulating layers 210 are disposed. Referring to FIG. 4, the active regions AR extend in the first direction (e.g., Y direction). On the first active regions ARI are disposed the gate electrodes 200, and on the second active regions AR2 are disposed the second insulating layers 210. The first active regions AR1 and the second active regions AR2 are alternately disposed.

According to an embodiment, as illustrated in FIG. 5, lower portions of the first air gaps 180 are disposed between the active regions AR, and upper portions of the first air gaps 180 are disposed between the storage layer patterns 120 disposed on the active regions AR. According to an embodiment, the upper portions of the first air gaps 180 are disposed above the active regions AR of the substrate 100. Accordingly, a dielectric constant of the first insulating layers 170 disposed between the memory cells MC may be lowered to thereby reduce disturbance between the memory cells MC, thereby resulting in an increase in product reliability. As illustrated in FIG. 5, the upper portions of the second air gaps 185 are exposed and no insulating layers are formed on the upper portions of the second air gaps 185.

In an embodiment, a width W1 of the first air gaps 180 is different from a width W2 of the second air gaps 185. According to an embodiment, the width W1 of the first air gaps 180 is smaller than the width W2 of the second air gaps 185. Thus, the first and second air gaps 180 and 185 having different widths W1 and W2 are alternately disposed in the first direction (e.g., Y direction).

In an embodiment, a depth T1 of the first air gaps 180 measured from top surfaces of the active regions AR is different from a depth T2 of the second air gaps 185 measured from the top surfaces of the active regions AR. According to an embodiment, the depth T1 of the first air gaps 180 is smaller than the depth T2 of the second air gaps 185.

The disturbance between the memory cells MC may be reduced by the first air gaps 180. As the size of the first air gaps 180 increases, the dielectric constant of the first insulating layers 170 decreases, so that the disturbance between the memory cells MC may be further reduced. However, as the size of the first air gaps 180 increases, the first air gaps 180 approach the adjacent tunnel insulating layer patterns 110, so that the charges stored in the storage layer patterns 120 may be discharged, thus resulting in a deterioration of the endurance characteristics of the memory cells MC.

In an embodiment, the width W1 and the depth T1 of the first air gaps 180 adjacent to the tunnel insulating layer patterns 110 are formed to be relatively small to thereby prevent the deterioration of the endurance characteristics of the memory cells MC. The width W2 and the depth T2 of the second air gaps 185 relatively distant from the tunnel insulating layer patterns 110 are formed to be relatively large compared to the width W1 and the depth T1 of the first air gaps 180 to thereby reduce the dielectric constant of the first insulating layers 170 and the disturbance between the memory cells MC. Thus, the non-volatile memory device in accordance with an embodiment may have high endurance characteristics and low disturbance between the memory cells MC, so that the reliability of the device can be increased.

Referring again to FIGS. 4 and 5, the second insulating layers 210 are disposed between the gate electrodes 200. The second insulating layers 210 extend in the second direction (e.g., X direction) substantially in parallel to the gate electrodes 200. The second insulating layers 210 include third air gaps 220 disposed to extend in the second direction (e.g., X direction).

The third air gaps 220 are disposed at a level higher than levels of the first and second air gaps 180 and 185 as illustrated in FIG. 5. According to an embodiment, the third air gaps 220 intersect and overlap the second air gaps 185 between the second active regions AR2. In an embodiment, the second air gaps 185 and the third air gaps 220 are connected to each other as illustrated in FIG. 5. Since the insulating layers are not formed on the second air gaps 185, the second air gaps 185 and the third air gaps 220 are connected to each other.

Lower portions of the third air gaps 220 are disposed between the storage layer patterns 120. According to an embodiment, the third air gaps 220 are disposed between the gate electrodes 200, between the blocking insulating layers 190 and between the storage layer patterns 120 as illustrated in FIG. 5.

A method for fabricating a non-volatile memory device in accordance with an embodiment of the present invention will be described with reference to FIGS. 5 to 12.

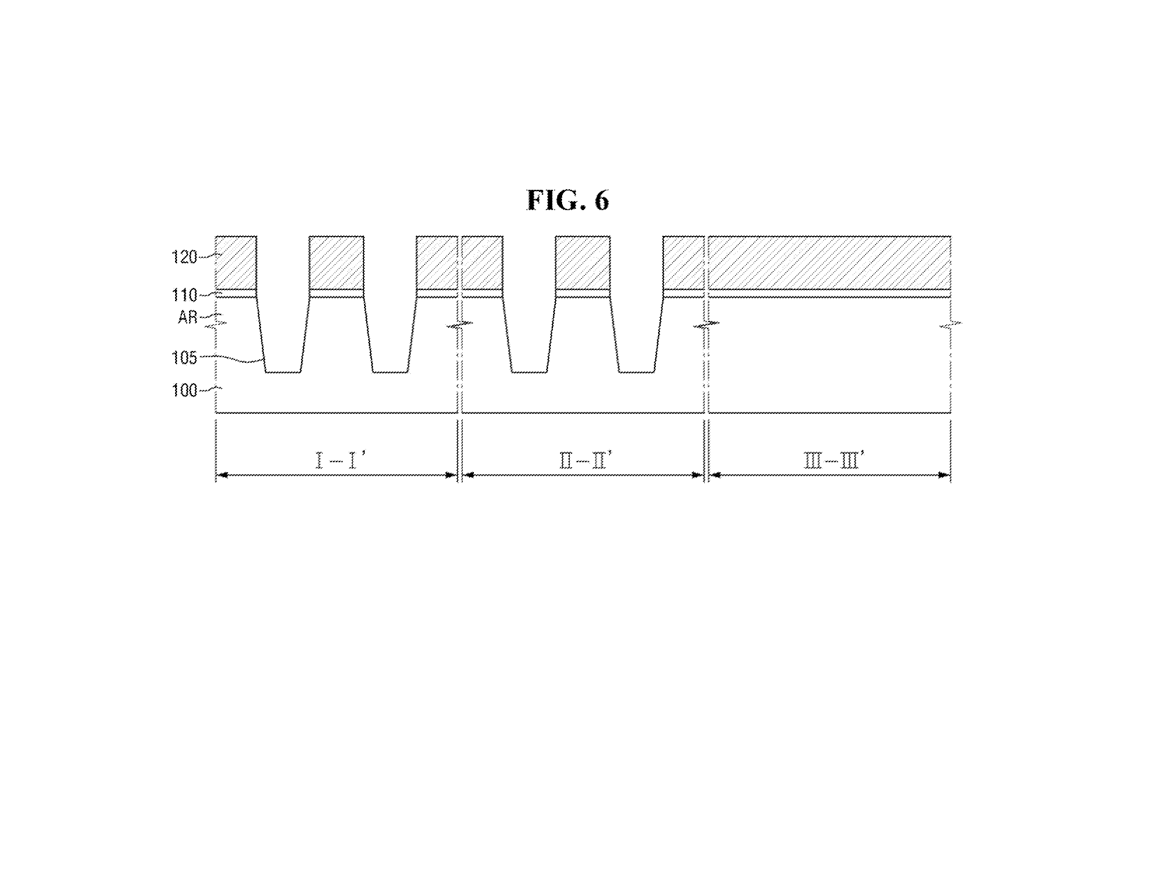

FIGS. 6 to 12 illustrate steps for describing a method for fabricating a non-volatile memory device in accordance with an embodiment of the present invention.

Referring to FIG. 6, the active regions AR are formed in the substrate 100 by the element isolation trenches 105 extending in the first direction (e.g., Y direction). The tunnel insulating layer patterns 110 and the storage layer patterns 120 are sequentially stacked on the active regions AR of the substrate 100.

Specifically, for example, a first dielectric layer (not shown) is formed on the substrate 100 by, e.g., chemical vapor deposition (CVD). In an embodiment, the first dielectric layer (not shown) includes, but is not limited to, HfₓSi₁₋ₓO_{y}.

Subsequently, a first conductive layer (not shown) is formed on the first dielectric layer (not shown) by, e.g., chemical vapor deposition (CVD). In an embodiment, the first conductive layer (not shown) includes, but is not limited to, polysilicon.

Then, the first dielectric layer (not shown) and the first conductive layer (not shown) are patterned by photolithography. In an embodiment, the element isolation trenches 105 are formed to define the active regions AR in the substrate 100. For example, after the first dielectric layer (not shown) and the first conductive layer (not shown) are sequentially formed on the substrate 100, the storage layer patterns 120 are formed by patterning first conductive layer (not shown), the tunnel insulating layer patterns 110 are formed by patterning the first dielectric layer (not shown), and the element isolation trenches 105 are formed by patterning the substrate 100.

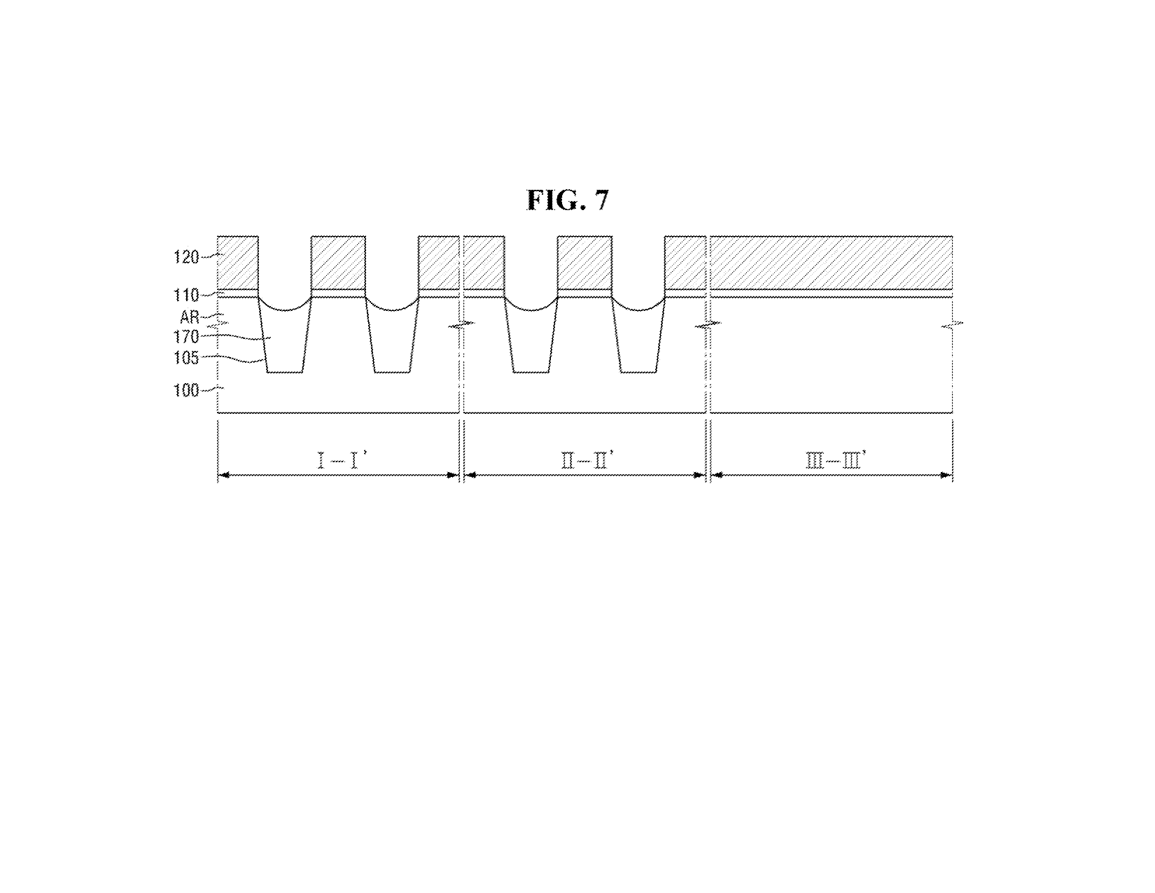

Referring to FIG. 7, the element isolation trenches 105 are filled with a first insulating material 170 by, e.g., chemical vapor deposition (CVD). In an embodiment, the first insulating material 170 includes, e.g., oxide or nitride.

Subsequently, the first insulating material 170 is selectively removed. Specifically, an upper portion of the first insulating material 170 in the element isolation trenches 105 is removed so that sidewalls of the storage layer patterns 120 are exposed.

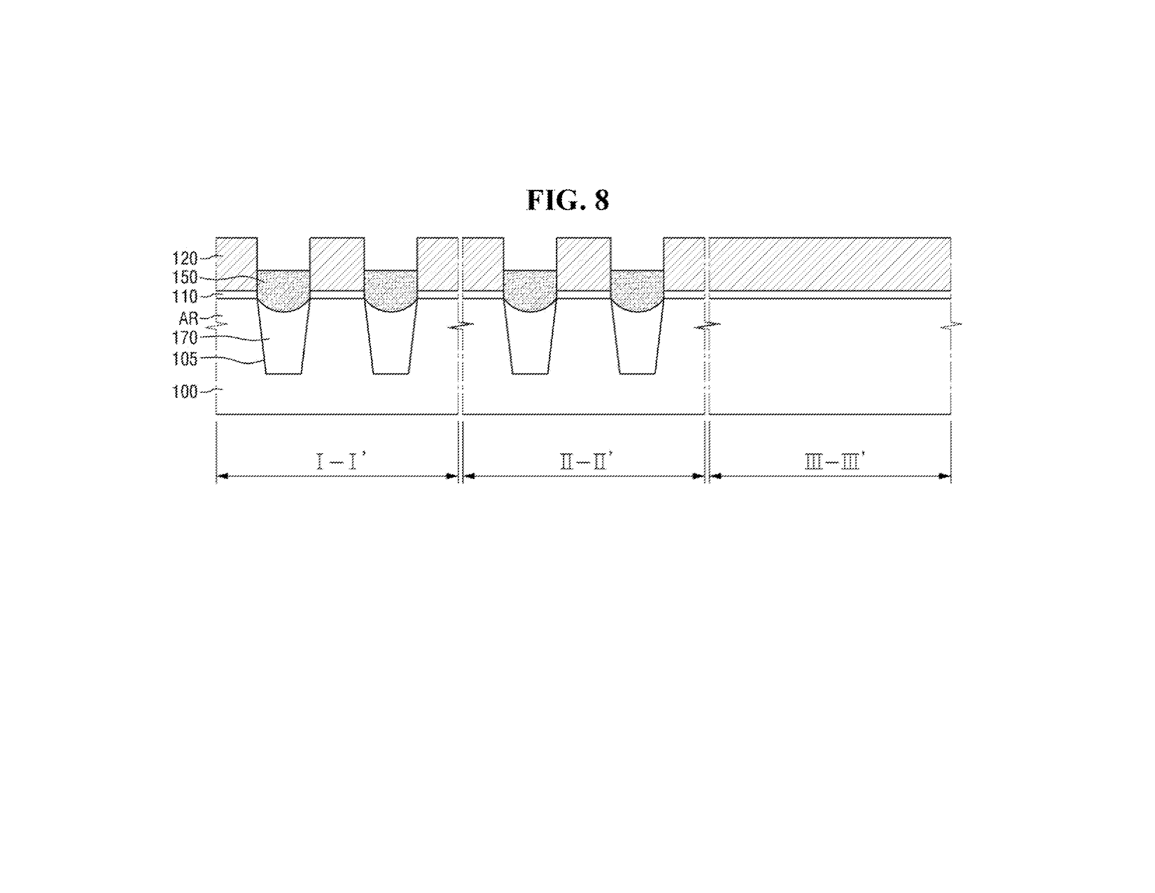

Then, referring to FIG. 8, a sacrificial layer 150 is formed on the first insulating material 170. In an embodiment, the sacrificial layer 150 is formed by using, e.g., chemical vapor deposition (CVD). According to an embodiment, the sacrificial layer 150 includes, e.g., a spin-on hardmask (SOH) or silicon nitride (SiN) layer, but the embodiments of the present invention are not limited thereto.

Subsequently, the sidewalls of the storage layer patterns 120 are exposed by removing an upper portion of the sacrificial layer 150 by performing, e.g., etching such as an etch-back process.

Spaces occupied by the remaining portions of sacrificial layer 150 may be turned into the first air gaps 180 by a subsequent step. Accordingly, the upper portion of the sacrificial layer 150 is removed such that the first air gaps 180 (see FIG. 5) are formed in the element isolation trenches 105. In an embodiment of the present invention, as illustrated in FIG. 8, the sacrificial layer 150 remains between the storage layer patterns 120 and between the active regions AR of the substrate 100.

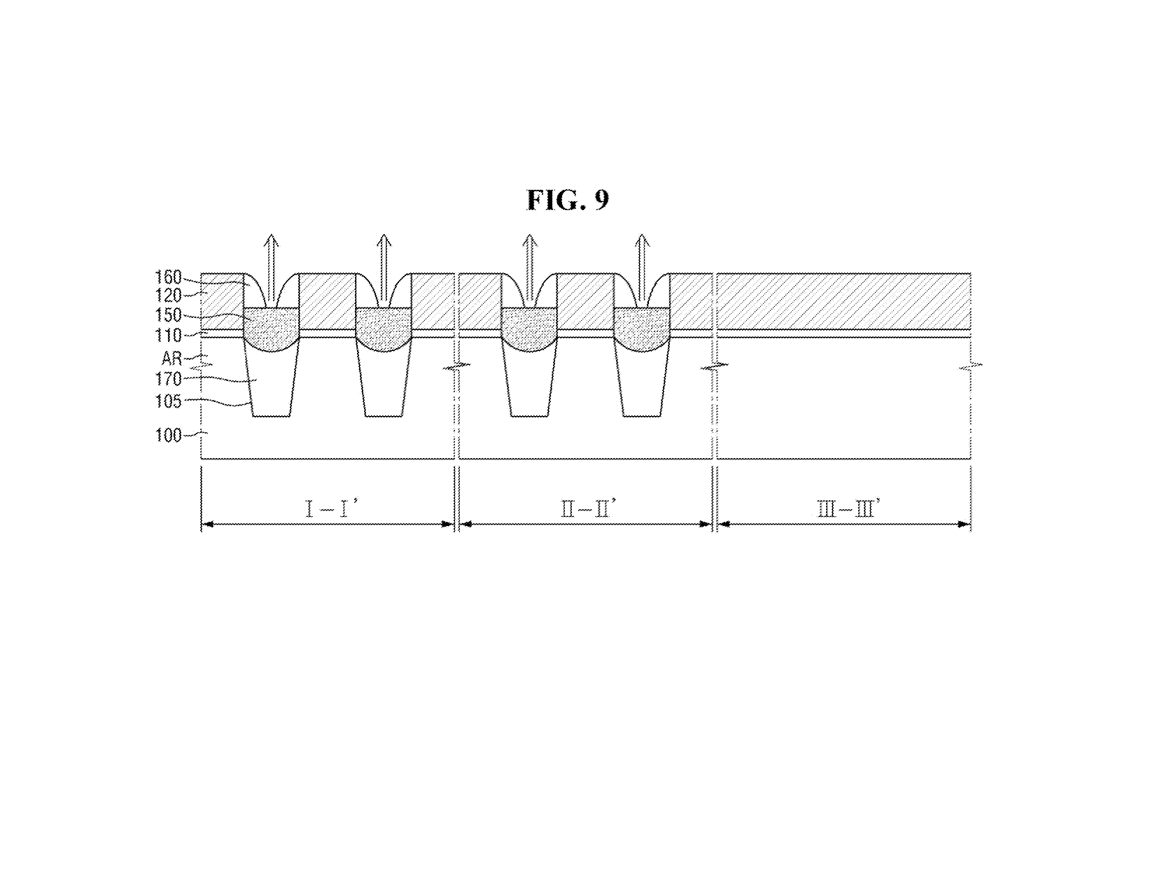

Then, referring to FIG. 9, a second insulating material 160 is formed on the remaining portions of the sacrificial layer 150. Specifically, the second insulating material 160 is formed on the sacrificial layer 150 while exposing a portion of an upper surface of the sacrificial layer 150.

As described above, forming the second insulating material 160 on the remaining sacrificial layer 150 includes forming spacers at two sidewalls of the storage layer patterns 120 exposed by the remaining portions of the sacrificial layer 150. Each of the spacers formed of the second insulating material 160 has one side contacting an adjacent one of the storage layer patterns 120 and another side remaining in an exposed state, and each spacer is separate from another spacer adjacent thereto, thereby exposing a portion of the upper surface of the sacrificial layer 150 below the spacers.

Subsequently, the sacrificial layer 150 remaining below the spacers formed of the second insulating material 160 is removed. According to an embodiment, the sacrificial layer 150 is selectively removed by, e.g., dry etching or wet etching. According to an embodiment, by adjusting processing conditions, such as processing time and etching gas, not only the exposed portion of the upper surface of the sacrificial layer 150 but also an unexposed portion of the sacrificial layer 150 may be removed. According to an embodiment, the sacrificial layer 150 is selectively removed by using etching selectivity between the sacrificial layer 150 and the second insulating material 160 and between the sacrificial layer 150 and the storage layer patterns 120.

For example, when the sacrificial layer 150 is formed of a spin-on mask, the exposed and unexposed portions of the sacrificial layer 150 are removed by ashing. When the sacrificial layer 150 is formed of a silicon nitride layer, the etching selectivity of the sacrificial layer 150 is increased by using a phosphoric acid. However, the embodiments of the present invention are not limited thereto, and according to embodiments, the sacrificial layer 150 may be selectively removed by various methods.

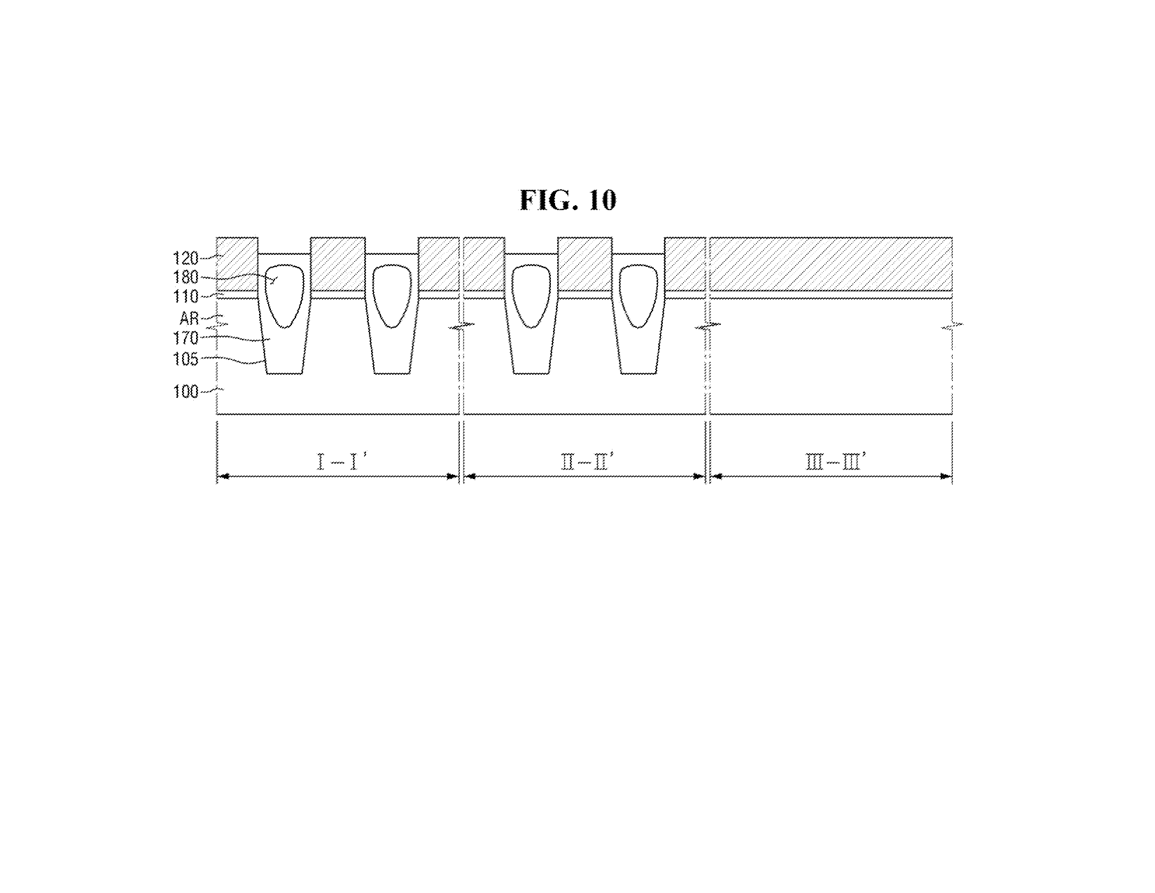

Referring to FIG. 10, a third insulating material (not shown) is formed on the spacers formed of the second insulating material 160. According to an embodiment, spaces from which the sacrificial layer 150 (see FIG. 9) is selectively removed are not filled with the third insulating material (not shown).

Specifically, for example, the third insulating material (not shown) is formed by using a material or deposition method having relatively low step coverage characteristics. More specifically, the third insulating material (not shown) is formed on the spacers formed of the second insulating material 160 such that the third insulating material (not shown) is embedded in the separation spaces between the spacers formed of the second insulating material 160 while maintaining the spaces occupied by the removed sacrificial layer 150. In other words, processing conditions are adjusted such that the third insulating material (not shown) fills the separation spaces between the spacers formed of the second insulating material 160 without filling the spaces formed by the removed sacrificial layer 150.

Subsequently, by selectively removing an upper portion of the third insulating material (not shown), the first insulating layers 170 including the first air gaps 180 are formed in the element isolation trenches 105.

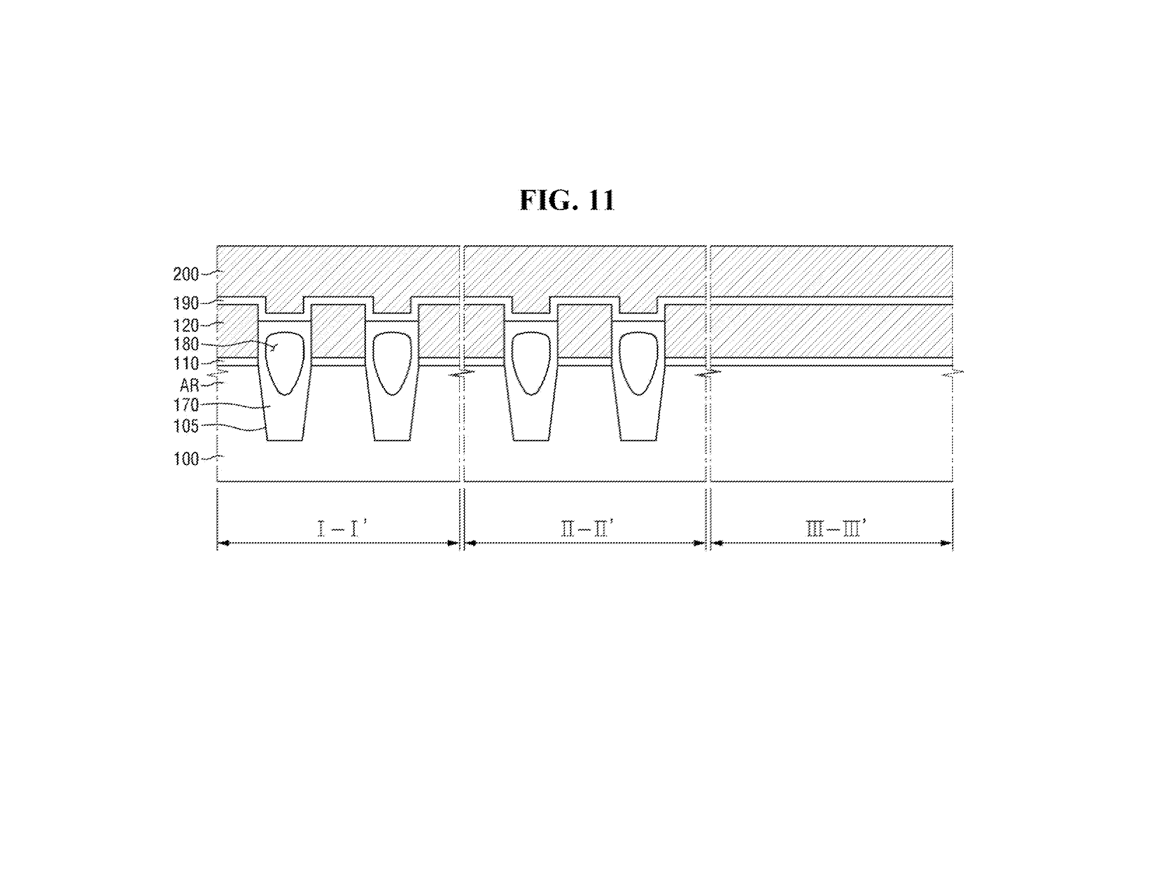

Referring to FIG. 11, a second dielectric layer 190 and a second conductive layer 200 extending in the second direction (e.g., X direction) perpendicular to the first direction (e.g., Y direction) are sequentially formed on the storage layer patterns 120 and the first insulating layers 170. According to an embodiment, for example, the second dielectric layer 190 is formed of a single layer or multiple layers using at least one of SiO₂, HfₓO_{y}, AlₓO_{y}, ZrₓO_{y}, TaₓO_{y}, HfₓSi₁₋ₓO_{y}, or HfₓSi₁₋ₓO_{y}N_{z}, but the embodiments of the present invention are not limited thereto.

According to an embodiment, the second conductive layer 200 is formed of a single layer or multiple layers including two or more material layers. For example, according to an embodiment, the second conductive layer 200 is formed by sequentially stacking a lower conductive line and an upper conductive line, and the stack structure of the lower and upper conductive lines includes one of metal and metal barrier layers, metal and impurity-doped polycrystalline silicon layers, metal silicide and metal silicide layers, and metal silicide and impurity-doped polycrystalline silicon layers.

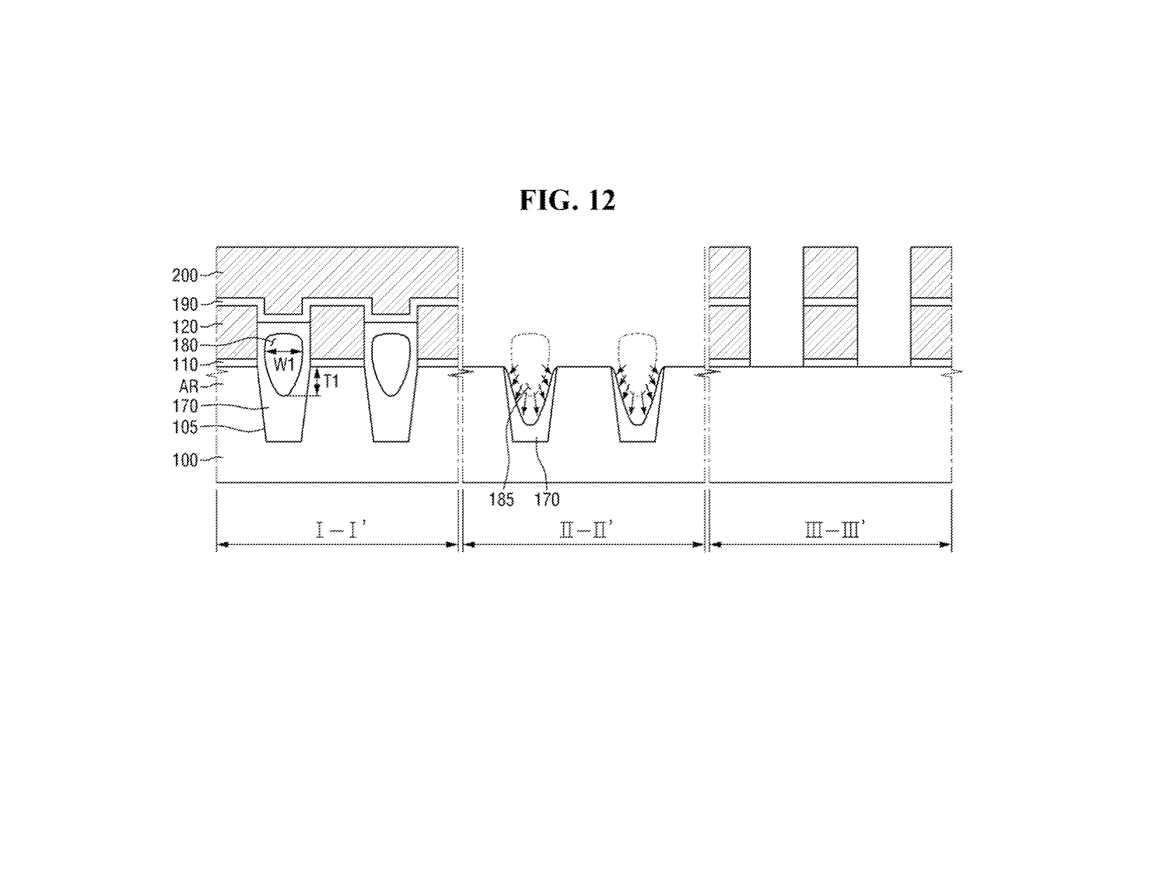

Referring to FIG. 12, the second conductive layer 200 and the second dielectric layer 190 are sequentially patterned to thereby form the gate electrodes 200 and the blocking insulating layers 190 extending in the second direction (e.g., X direction).

According to an embodiment, portions of the first insulating layers 170 and the storage layer patterns 120 are exposed in regions where the second conductive layer 200 and the second dielectric layer 190 are removed. In other words, the storage layer patterns 120 formed on the second active regions AR2 and the portions of the first insulating layers 170 adjacent to the second active regions AR2 are exposed by patterning the second conductive layer 200 and the second dielectric layer 190.

Subsequently, the exposed storage layer patterns 120 formed on the second active regions AR2 are etched to expose the tunnel insulating layer patterns 110 disposed below the storage layer patterns 120. According to an embodiment, the portions of the first insulating layers 170 adjacent to the etched storage layer patterns 120 are etched as well. By the etching, the upper portions of the first insulating layers 170 are removed, and the portions of the first insulating layers 170 formed at two sidewalls of the element isolation trenches 105 are also etched.

Thereafter, the tunnel insulating layer patterns 110 are exposed, and the exposed tunnel insulating layer patterns 110 are etched to expose the second active regions AR2. According to an embodiment, the portions of the first insulating layers 170 adjacent to the etched tunnel insulating layer patterns 110 are etched as well. Accordingly, the portions of the first insulating layers 170 formed at two sidewalls of the element isolation trenches 105 adjacent to the etched tunnel insulating layer patterns 110 are also etched.

As the exposed portions of the first insulating layers 170 are continuously etched, the air gaps included in the first insulating layers 170 adjacent to the second active regions AR2 have the width W2 and the depth T2 after etching, which are larger than the width W1 and the depth T1 before etching. In other words, the width W2 and the depth

T2 of the second air gaps 185 included in the first insulating layers 170 adjacent to the second active regions AR2 become larger than the width W1 and the depth T1 of the first air gaps 180 included in the first insulating layers 170 adjacent to the first active regions AR1.

Referring back to FIG. 5, the second insulating layers 210 are formed on the exposed second active regions AR2 and the exposed first insulating layers 170 in the second direction (e.g., X direction). According to an embodiment, the second insulating layers 210 are formed by using an insulating material or deposition method having relatively low step coverage characteristics.

Due to the relatively low step coverage characteristics, the second insulating layers 210 are formed along sidewalls of the gate electrodes 200 and the storage layer patterns 120 adjacent thereto. Thus, as illustrated in FIG. 5, the second insulating layers 210 includes the third air gaps 220 formed between the gate electrodes 200, between the blocking insulating layers 190 and between the storage layer patterns 120.

Since the exposed first insulating layers 170 include the second air gaps 185 whose upper portions are exposed, when the second insulating layers 210 are formed on the exposed first insulating layers 170, the third air gaps 220 and the second air gaps 185 can be connected to each other at areas where the third air gaps 220 intersect the second air gaps 185.

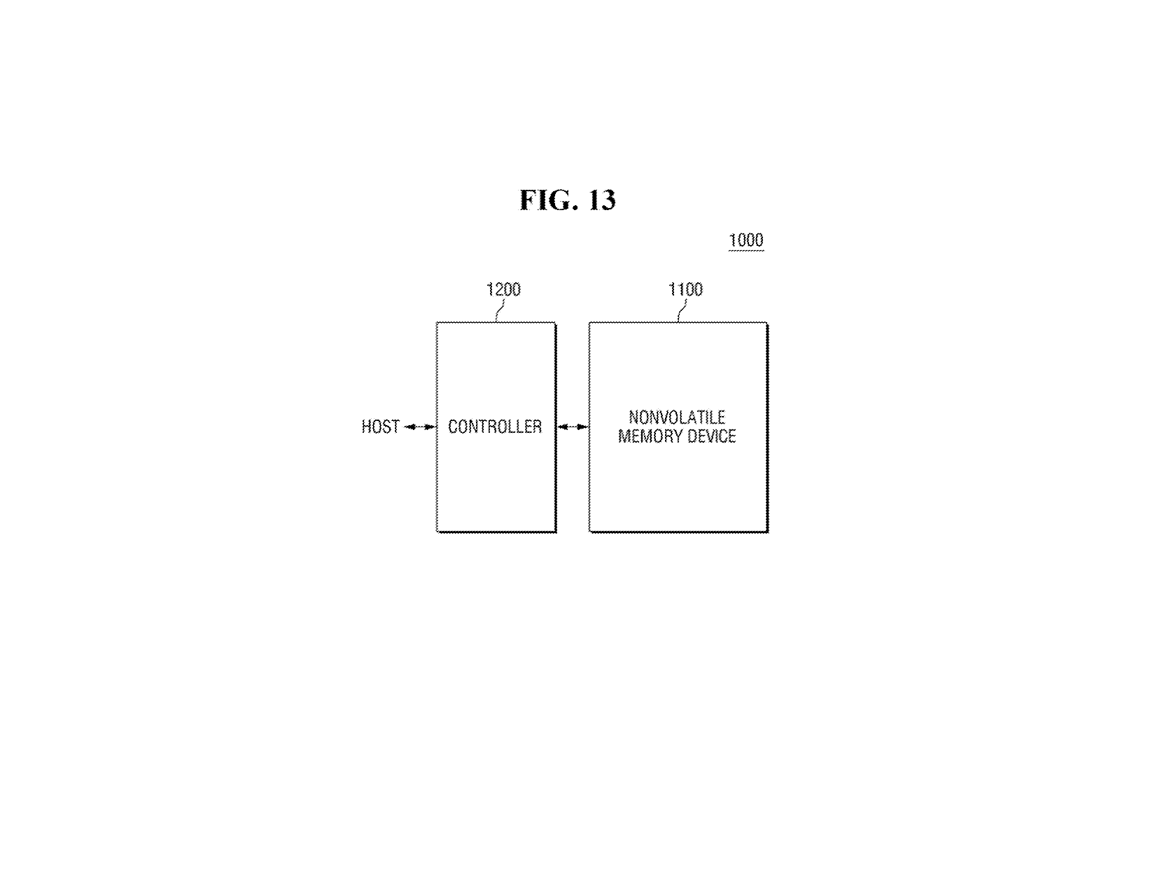

Hereinafter, a memory system in accordance with an embodiment of the present invention and application examples thereof are described with reference to FIGS. 13 to 15.

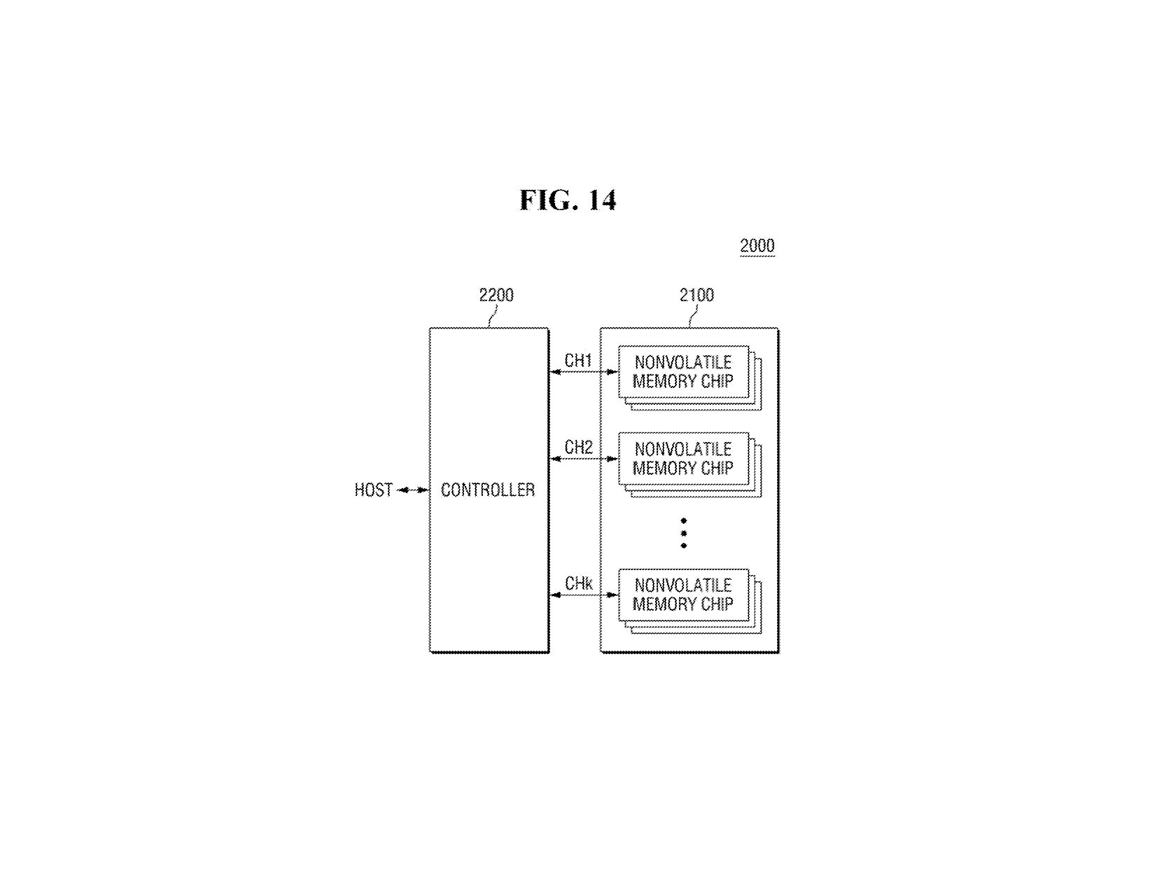

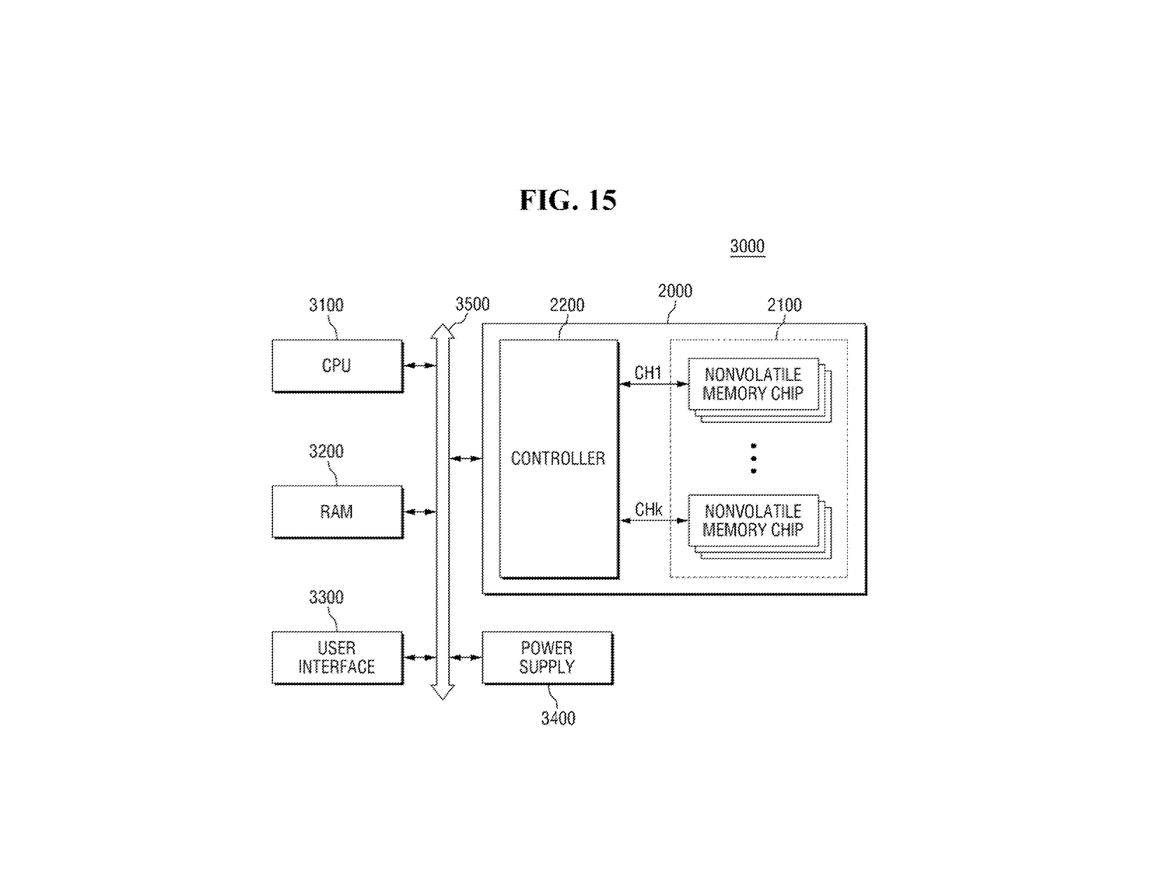

FIG. 13 is a block diagram for describing a memory system in accordance with an embodiment of the present invention. FIG. 14 is a block diagram showing an application example of the memory system of FIG. 13. FIG. 15 is a block diagram showing a computing system including the memory system described with reference to FIG. 14.

Referring to FIG. 13, a memory system 1000 includes a nonvolatile memory device 1100 and a controller 1200.

The nonvolatile memory device 1100 includes the above-described non-volatile memory device with improved reliability.

The controller 1200 is connected to a host and the nonvolatile memory device 1100. In response to a request of the host, the controller 1200 is configured to access the nonvolatile memory device 1100. For example, the controller 1200 is configured to control read, write, erase and background operations of the nonvolatile memory device 1100. The controller 1200 is configured to provide an interface between the nonvolatile memory device 1100 and the host. The controller 1200 is configured to operate firmware for controlling the nonvolatile memory device 1100.

According to an embodiment, the controller 1200 further includes well-known components, such as a random access memory (RAM), a processing unit, a host interface, and a memory interface. The RAM is used as at least one of an operation memory of the processing unit, a cache memory between the nonvolatile memory device 1100 and the host, and a buffer memory between the nonvolatile memory device 1100 and the host. The processing unit controls all operations of the controller 1200.

The host interface includes a protocol for performing data exchange between the hose and the controller 1200. For example, the controller 1200 is configured to perform communication with the outside (host) through at least one of various interface protocols, such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol. The memory interface interfaces with the nonvolatile memory device 1100. For example, the memory interface includes a NAND interface or NOR interface.

According to an embodiment, the memory system 1000 further includes an error correction block. The error correction block is configured to detect and correct an error of data read from the nonvolatile memory device 1100 using an error correction code (ECC). As an example, the error correction block is provided as a component of the controller 1200. Alternatively, the error correction block is provided as a component of the nonvolatile memory device 1100.

According to an embodiment, the controller 1200 and the nonvolatile memory device 1100 are integrated as one semiconductor device to thereby constitute a memory card, such as a PC card (personal computer memory card international association (PCMCIA)), a compact flash card (CF), a smart media card (SM, SMC), a memory stick, a multimedia card (MMC, RS-MMC, MMCmicro), a SD card (SD, miniSD, microSD, SDHC), or a universal flash storage device (UFS).

Alternatively, the controller 1200 and the nonvolatile memory device 1100 are integrated as one semiconductor device to thereby constitute a semiconductor drive (solid state drive (SSD)). The semiconductor drive (SSD) includes a storage device configured to store data in a semiconductor memory. In a case where the memory system 1000 is used as the semiconductor drive (SSD), an operation speed of the host connected to the memory system 1000 is dramatically improved.

As another example, the memory system 1000 is provided as one of various components of an electronic apparatus, such as a computer, ultra mobile PC (UMPC), workstation, net-book, personal digital assistants (PDA), portable computer, web tablet, wireless phone, mobile phone, smart phone, e-book, portable multimedia player (PMP), portable game console, navigation device, black box, digital camera, 3-dimensional television, digital audio recorder, digital audio player, digital picture recorder, digital picture player, digital video recorder, digital video player, apparatus capable of transmitting and receiving information in wireless environment, one of various electronic apparatuses constituting the home network, one of various electronic apparatuses constituting the computer network, one of various electronic apparatuses constituting the telematics network, RFID device, and one of various components forming the computing system.

According to an embodiment, the nonvolatile memory device 1100 or the memory system 1000 is mounted in various types of packages. For example, the nonvolatile memory device 1100 or the memory system 1000 is mounted in a package, such as package on package (PoP), ball grid arrays (BGAs), chip scale packages (CSPs), plastic leaded chip carrier(PLCC), plastic dual in line package (PDIP), die in waffle pack, die in wafer form, chip on board (COB), ceramic dual in line package (CERDIP), plastic metric quad flat pack (MQFP), thin quad flat pack (TQFP), small outline (SOIC), shrink small outline package (SSOP), thin small outline (TSOP), thin quad flat pack (TQFP), system in package (SIP), multi chip package (MCP), wafer-level fabricated package (WFP), or wafer-level processed stack package (WSP).

Referring to FIG. 14, a memory system 2000 includes a nonvolatile memory device 2100 and a controller 2200. The nonvolatile memory device 2100 includes a plurality of nonvolatile memory chips. The nonvolatile memory chips are classified into a plurality of groups. Each group of the nonvolatile memory chips is configured to perform communication with the controller 2200 via one common channel. For example, the nonvolatile memory chips perform communication with the controller 2200 via first to k-th channels CH1 to CHk.

An example where a plurality of nonvolatile memory chips are connected to one channel has been illustrated in FIG. 14. However, according to an embodiment, the memory system 2000 is modified such that one nonvolatile memory chip is connected to one channel.

Referring to FIG. 15, a computing system 3000 includes a central processing unit 3100, a random access memory (RAM) 3200, a user interface 3300, a power supply 3400, and the memory system 2000.

The memory system 2000 is electrically connected to the central processing unit 3100, the RAM 3200, the user interface 3300 and the power supply 3400 via a system bus 3500. The data provided through the user interface 3300 or processed by the central processing unit 3100 is stored in the memory system 2000.

FIG. 15 illustrates an example where the nonvolatile memory device 2100 is connected to the system bus 3500 through the controller 2200. However, according to an embodiment, the nonvolatile memory device 2100 is configured to be directly connected to the system bus 3500.

An example of providing the memory system 2000 described with reference to FIG. 14 has been illustrated in FIG. 15. However, according to an embodiment, the memory system 2000 is replaced by the memory system 1000 described with reference to FIG. 13.

For instance, according to an embodiment, the computing system 3000 is configured to include all of the memory systems 1000 and 2000 described with reference to FIGS. 13 and 14.

Those skilled in the art will appreciate that many variations and modifications can be made to the embodiments without substantially departing from the principles of the embodiments of the present invention.

1. A non-volatile memory device comprising:
a substrate including a plurality of active regions sequentially disposed and extending in a first direction and a plurality of element isolation trenches disposed between the active regions;
a plurality of tunnel insulating layer patterns and a plurality of storage layer patterns sequentially disposed on the substrate;
a plurality of blocking insulating layers and a plurality of gate electrodes sequentially disposed on the storage layer patterns and extending in a second direction perpendicular to the first direction; and
first insulating layers including air gaps, the first insulating layers disposed between the active regions in the element isolation trenches, wherein the first insulating layers extend in the first direction,
wherein the active regions include first active regions and second active regions adjacent to the first active regions,
wherein the air gaps include first air gaps disposed between the first active regions and second air gaps disposed between the second active regions, and
wherein a width of the first air gaps is different from a width of the second air gaps.

2. The non-volatile memory device of claim 1, wherein the width of the first air gaps is smaller than the width of the second air gaps.

3. The non-volatile memory device of claim 1, wherein a depth of the first air gaps is different from a depth of the second air gaps.

4. The non-volatile memory device of claim 3, wherein the depth of the first air gaps is smaller than the depth of the second air gaps.

5. The non-volatile memory device of claim 1, wherein at least portions of the first air gaps are disposed between the storage layer patterns.

6. The non-volatile memory device of claim 1, further comprising second insulating layers including third air gaps disposed between the gate electrodes, wherein the second insulating layers extend in the second direction substantially parallel to the gate electrodes.

7. The non-volatile memory device of claim 6, wherein the second air gaps and the third air gaps overlap each other.

8. The non-volatile memory device of claim 7, wherein the second air gaps and the third air gaps are connected to each other.

9. The non-volatile memory device of claim 6, wherein the gate electrodes are disposed on the first active regions, and the second insulating layers are disposed on the second active regions.

10. The non-volatile memory device of claim 6, wherein at least portions of the third air gaps are disposed between the storage layer patterns.

11. The non-volatile memory device of claim 1, wherein the gate electrodes are disposed on the first active regions, but not on the second active regions.

12. A non-volatile memory device comprising:
a substrate including a plurality of active regions sequentially disposed and extending in a first direction and a plurality of element isolation trenches disposed between the active regions;
a plurality of tunnel insulating layer patterns and a plurality of storage layer patterns sequentially disposed on the substrate;
a plurality of blocking insulating layers and a plurality of gate electrodes sequentially disposed on the storage layer patterns and extending in a second direction perpendicular to the first direction;
first air gaps disposed between the active regions and extending in the first direction; and
second air gaps disposed between the gate electrodes and extending in the second direction,
wherein a width of some of the first air gaps that intersect the second air gaps is different from a width of others of the first air gaps that do not intersect the second air gaps.

13. The non-volatile memory device of claim 12, wherein the width of the some of the first air gaps that intersect the second air gaps is larger than the width of the others of the first air gaps that do not intersect the second air gaps.

14. The non-volatile memory device of claim 12, wherein a depth of the some of the first air gaps that intersect the second air gaps is different from a depth of the others of the first air gaps that do not intersect the second air gaps.

15. The non-volatile memory device of claim 12, wherein the second air gaps and the some of the first air gaps that intersect the second air gaps are connected to each other.

16-20. (canceled)
